(19) United States
(12) Patent Application Publication
(10) Pub. No.: US 2010/0321027 A1
(43) Pub. Date: Dec. 23, 2010

(54) Methods and Systems for Detection Using Threshold-Type Electrostatic Sensors

(76) Inventors: Mahmoud Elsayed Khater, Kitchener (CA); Eihab Mohamed Abdel-Rahman, Waterloo (CA); Ali Hasan Nayfeh, Blacksburg, VA (US)

Correspondence Address: DOWELL & DOWELL P.C., 103 Oronoco St., Suite 220, Alexandria, VA, 22314, US

(21) Appl. No.: 12/791,293

(22) Filed: Jun. 1, 2010

Related U.S. Application Data
(60) Provisional application No. 61/182,690, filed on May 30, 2009.

(51) Int. Cl. G01N 27/60; G01R 19/04

(52) U.S. Cl. 324/452; 324/103 P

(57) ABSTRACT

Methods, apparatus and systems are described as relating to electrostatic sensors for detection in micro or nano electromechanical systems. In exemplary embodiments, a sensor for detecting a threshold value of is provided. The sensor includes a deformable member with a mass detection area, an electrostatic actuator having first and second plates, the first plate being connected to the mass detection area, and a voltage source connected to each of the first and second plate. The operating voltage being proximate to a local bifurcation point of the electrostatic sensor for the first and second plates to pull-in together. Upon an external mass having the threshold value appearing on the mass detection area, the local bifurcation point of the electrostatic sensor is shifted such that the first and second plates will pull in to contact each other by movement of the deformable member to signal detection.

### RELATED APPLICATIONS

This application claims priority from U.S. Provisional Application 61/182,690 filed May 30, 2009, the contents of which are herein incorporated by reference.

### FIELD

The methods, apparatus and systems described herein relate to electrostatic sensors for mass, gas, chemical and biological material detection in micro or nano electromechanical systems, and more specifically to the use of threshold-type electrostatic sensors for use in mass, gas, chemical or biological material detection.

### SUMMARY OF THE INVENTION

In an aspect of the present invention, there is provided a threshold-type electrostatic sensor for detecting a threshold value of mass comprising: a deformable member with a mass detection area thereon; an electrostatic actuator having a first plate and a second plate, the first plate being connected to the mass detection area; and a voltage source connected to each of the first and second plates. The voltage source provides an operating voltage to the actuator, the operating voltage being proximate to a local bifurcation point of the electrostatic sensor for the first and second plates to pull-in together. Upon an external mass having the threshold value appearing on the mass detection area, the local bifurcation point of the electrostatic sensor is shifted such that the first and second plates will pull-in to contact each other by movement of the deformable member, the contact providing signalling indicative of detection of the threshold value of the external mass.

The threshold-type electrostatic sensor may further comprise output device for receiving the signaling of detection of the external mass. The second plates may be mounted on a substrate and the first plate may be mounted over the second plate by way of the deformable member attached to a post on the substrate.

The pull-in of the first and second plates may be by static pull-in and the local bifurcation point may be determined by saddle-node bifurcation. The threshold-type electrostatic sensor may further comprise a non-linear controller electrically connected to the voltage source and the electrostatic actuator, wherein the local bifurcation point may be determined by any one of sub-critical pitch-fork bifurcation or saddle-node bifurcation.

The pull-in of the first and second plates may be by dynamic pull-in and the local bifurcation point may be determined by cyclic-fold bifurcation. The threshold-type electrostatic sensor may further comprise a non-linear controller electrically connected to the voltage source and the electrostatic actuator and the local bifurcation point may be determined by any one of sub-critical period doubling bifurcation, sub-critical Hopf bifurcation or cyclic-fold bifurcation.

In another aspect of the present invention, there is provided a threshold-type electrostatic sensor for detecting a threshold value of a concentration of an analyte comprising: a deformable member; an electrostatic actuator having a first plate and a second plate and a concentration detection region therebetween; and a voltage source connected to each of the first and second plates. The voltage source provides an operating voltage to the actuator, the operating voltage being proximate to a local bifurcation point of the electrostatic sensor for the first and second plates to pull-in together. Upon an external concentration of an analyte having the threshold value appearing in the detection region, the local bifurcation point of the electrostatic sensor is shifted such that the first and second plates will pull-in to contact each other by movement of the deformable member, the contact providing signalling indicative of detection of the threshold value of the external concentration of the analyte.

The threshold-type electrostatic sensor may further comprise an output device for receiving the signaling of detection of the concentration of the analyte. The second plate may be mounted on a substrate and the first plate may be mounted over the second plate by way of the deformable member attached to a post on the substrate.

The pull-in of the first and second plates may be by static pull-in and the local bifurcation point may be determined by saddle-node bifurcation. The threshold-type electrostatic sensor may further comprise a non-linear controller electrically connected to the voltage source and the electrostatic actuator, wherein the local bifurcation point may be determined by any one of sub-critical pitch-fork bifurcation or saddle-node bufircuation.

The pull-in of the first and second plates may be by dynamic pull-in and the local bifurcation point may be determined by cyclic-fold bifurcation. The threshold-type electrostatic sensor may further comprise a non-linear controller electrically connected to the voltage source and the electrostatic actuator and the local bifurcation point may be determined by any one of sub-critical period doubling bifurcation, sub-critical Hopf bifurcation or cyclic-fold bifurcation.

The threshold-type electrostatic sensor may further comprise a circuit element made of a detector material connected to the first and second plates for adjustment of impedance therebetween in the presence of the analyte.

In other aspects, methods and apparatus relating to the systems described above are also provided.

### BRIEF DESCRIPTION OF THE FIGURES

For a better understanding of the embodiments of the system and methods described herein, and to show more clearly how they may be carried into effect, reference will be made by way of example, to the accompanying drawings in which:

FIG. 1 illustrates a block diagram of the system of a threshold-type electrostatic sensor;

FIG. 2 illustrates a block diagram of an embodiment of a threshold-type electrostatic sensor for detecting a threshold mass;

FIG. 3 illustrates a flowchart of an embodiment of a method for determining the threshold mass that may be required to achieve pull-in of the electrostatic actuator of the threshold-type electrostatic sensor of FIG. 2;

FIG. 4 illustrates a block diagram of an embodiment of a threshold-type electrostatic sensor;

FIG. 5 shows a representation of the static deflection of the plate of an electrostatic actuator of the threshold-type electrostatic sensor of FIG. 2 operated with a direct current operating voltage and the static pull-in point subsequent to a saddle-node bifurcation;

FIG. 6 shows a representation of the sensitivity of the threshold-type electrostatic sensor of FIG. 2 operated with a direct current operating voltage;

FIG. 7 shows a representation of minimum detectable masses versus various operating voltages of the threshold-type electrostatic sensor of FIG. 2 operating in static pull-in; and

FIG. 8 shows a representation of dynamic pull-in subsequent to a cyclic-fold bifurcation of the threshold-type electrostatic sensor of FIG. 2.

### DETAILED DESCRIPTION OF THE PREFERRED EMBODIMENTS

It will be appreciated that for simplicity and clarity of illustration, where considered appropriate, reference numerals may be repeated among the figures to indicate corresponding or analogous elements or steps. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description is not to be considered as limiting the scope of the embodiments described herein in any way, but rather as merely describing the implementation of the various embodiments described herein.

The methods and systems described herein tends to increase the efficiency by which detection of minute masses may be measured using micro or nano electromechanical systems. In some embodiments, such systems may be adapted to measure minute masses, concentrations of gases, concentration of chemicals or existence or concentration of biological material. In other embodiments, threshold-type electrostatic sensors described herein may use a threshold-type sensing mechanism that tend to determine whether the detected mass, gas concentration, chemical concentration, or biological material concentration is larger or smaller than concentration. In some embodiments threshold-type electrostatic sensors may tend to determine whether a biological material exists or does not exist in a medium. In other embodiments, multiple threshold-type electrostatic sensors may be configured in an array such that multiple output devices may receive signaling with such signaling being digitally processed which may tend to provide data regarding the composition of gases, chemical materials or biological materials being detected in the medium.

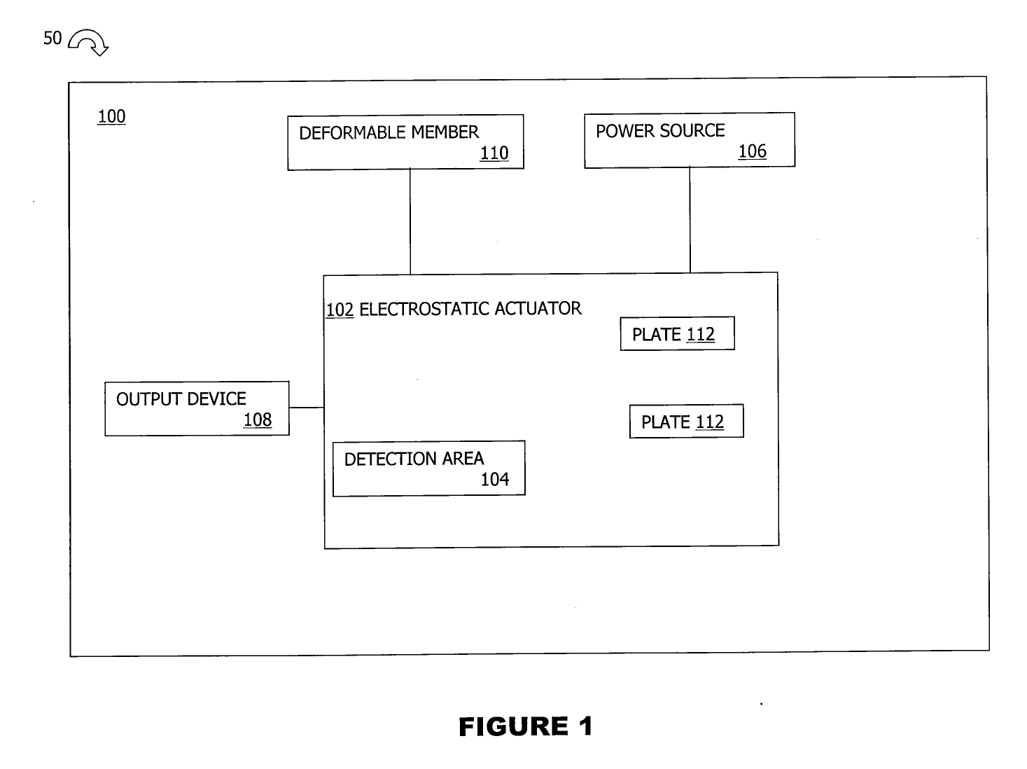

With reference to FIG. 1, a system 50 for use in minute mass detection is shown. The detection system 50 comprises a threshold type electrostatic sensor comprising an actuator 102 having detection area 104 and plates 112. In an embodiment, electrostatic actuator 102 is a capacitor. In such an embodiment detection area 104 may be attached to a surface of one of plates 112.

Threshold-type electrostatic sensor 100 further has voltage source 106 and output device 108 electrically connected to electrostatic actuator 102. Output device 108 is intended to provide feedback to a user of threshold-type electrostatic sensor 100 when the threshold-type electrostatic sensor 100 reaches the predefined threshold of detection, therefore indicating, that a particular preset mass threshold detection point has been reached, or a predefined concentration threshold of an analyte in, for example, a fluid, has been reached. The output device 108 may include, but is not limited to an LED, an audio device or a computer system for logging threshold events or any other such system by which a user may be alerted as to the operation of the sensor 100.

Voltage source 106 may be a direct current (DC) voltage source or, in some embodiments, may be an alternating current (AC) voltage source, and in other embodiments may be a combination of a DC and AC voltage source.

Deformable member 110 may be connected to electrostatic actuator 102 and, in an embodiment wherein electrostatic actuator 102 is an electrostatic capacitor, deformable member 110 may be connected to plate 112 having the detection area 104.

Threshold-type electrostatic sensor 100 has an associated local bifurcation point associated with a pull-in threshold, where once the pull-in threshold is reached, the electrostatic sensor 100 will change its binary state. The location of the local bifurcation point of threshold-type electrostatic sensor 100 is a function of the resistive force provided by deformable member 110, and original mass and additional mass added to threshold-type electrostatic sensor 100 by, for example, detection area 102 and the electrostatic properties of electrostatic actuator 102.

In operation, voltage source 106 provides an operating voltage to electrostatic actuator 102 where such operating voltage, in an embodiment, is close to the pull-in threshold associated with the local bifurcation point of threshold-type electrostatic sensor 100. In embodiments of threshold-type electrostatic sensor 100 for detecting mass threshold amounts, as the amount of additional external mass is received by detection area 104 the local bifurcation point of threshold-type electrostatic sensor 100 is adjusted. Once the threshold amount of mass is received by detection area 104 of electrostatic sensor 100 the operative voltage provided by voltage source 106 will cause pull-in due to the adjusted local bifurcation point (adjusted due to the mass received by detection area 104) altering the pull-in threshold such that the operating voltage has moved past the pull-in threshold (from the safe side of the local bifurcation point to the unsafe side of the local bifurcation point), achieving pull-in of electrostatic actuator 102. Achieving pull-in has the effect of providing a change of binary state of threshold-type electrostatic sensor 100. Upon the change of state of electrostatic sensor 100, output device 108 may alert a user that the threshold mass amount has been detected.

In some embodiments, threshold-type electrostatic sensor 100 may be a mass detection sensor and detection area 104 may be made from a structural material coated with a functional material to attract a particular analyte such as a particular gas, chemical or biological material. For example, detection area 104 may be made from a structural material such as crystalline silicon, polycrystalline silicon, or silicon nitride, and coated with a functional material such as polyvinylpyridine (PVP), polyurethane (PU), polystyrene (PS), or polymethylmethacrylate (PMMA) designed to attract ethanol vapor or water vapor from air.

In other embodiments, the threshold-type electrostatic sensor 100 may detect threshold concentration amounts of an analyte in a fluid. In such embodiments, analytes may be located between plates 112 of electrostatic actuator 102 which may tend to change the dielectric constant of electrostatic actuator 102. As the concentration levels of analytes increase to the threshold concentration the local bifurcation point of threshold-type electrostatic sensor 100 may be adjusted due to the change in the dielectric constant of electrostatic actuator 102 adjusting the electrostatic field between plates 112. When the concentration levels of analytes reach the threshold level, the operative voltage provided by voltage source 106 can cause pull-in due to the adjusted local bifurcation point (adjusted due to the concentration of analytes located between plates 112) altering the pull-in threshold such that the operating voltage has moved past the pull-in threshold (from the safe side of the local bifurcation point to the unsafe side of the local bifurcation point), achieving pull-in of electrostatic actuator 102. Achieving pull-in as described above, has the effect of changing the binary state of threshold-type electrostatic sensor 100. Upon the change of state, output device 108 may alert a user that the threshold concentration amount of an analyte has been detected.

In some embodiments, electrostatic actuator 102 may be connected in series or in parallel with additional circuitry which may provide additional functionality to adjust the electrostatic properties of electrostatic actuator 102. In such embodiments, such additional circuitry may be electrically connected (in series or in parallel) between plates 112 of electrostatic actuator 102, which, in the presence of a particular concentration of an analyte may interact with such additional circuitry, and may tend to increase the magnitude of the voltage drop between plates 112. In such embodiments, some of the additional circuit elements can be made of detector materials that may have properties such that in the presence of a particular analyte such additional circuit elements may tend to adjust their impedance thereby increasing the voltage drop between plates 112 of electrostatic actuator 102, which, in the presence of a particular concentration of analyte can tend to cause increase in the voltage drop across plates 112, which may increase the strength of the electrostatic field between plates 112. Such adjustments of the electrostatic field between the plates due to detected concentration levels can adjust the local bifurcation point of threshold-type bifurcation sensor 100, which can tend to alter the pull-in threshold such that the operating voltage may move past the pull-in threshold (from the safe side of the local bifurcation point to the unsafe side of the local bifurcation point), achieving pull-in of electrostatic actuator 102. Achieving pull-in as described above, has the effect of changing the binary state of threshold-type electrostatic sensor 100. Upon the change of state, output device 108 may alert a user that the threshold concentration amount of an analyte has been detected.

In some embodiments, threshold-type electrostatic sensor 100 may be operated using local static bifurcation, which may correspond to static pull-in. In such embodiments, threshold-type electrostatic sensor 100 may be operated according to saddle-node bifurcation or sub-critical pitch-fork bifurcation and use only DC voltage source. In embodiments operating by sub-critical pitch-fork bifurcation, and in some embodiments operating by a saddle-node bifurcation, an additional non-linear controller may be used to implement a closed-loop feedback system to stabilize the response of electrostatic actuator 102. In such embodiments, the non-linear controller may tend to take an output signal describing motions and change of electrostatic actuator 102 and change the input voltage appropriately. Alternatively, multiple specially design electrodes (plates 112), or structurally complex deformable members 110 may be used to create the sub-critical pitch-fork bifurcation or a saddle node bifurcation.

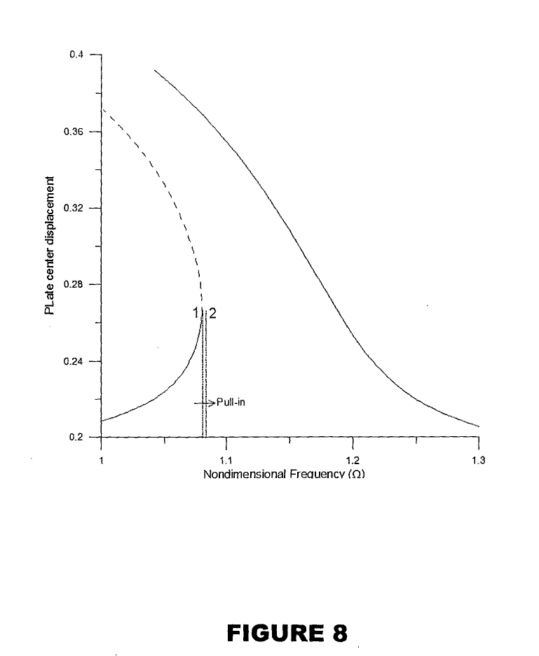

In other embodiments, threshold-type electrostatic sensor 100 may be operated using dynamic bifurcation. In some such embodiments, threshold-type electrostatic sensor 100 may operate using cyclic-fold bifurcation, sub-critical period doubling bifurcation or sub-critical Hopf bifurcation and use AC voltage source or a mixed DC and AC voltage source. FIG. 8 shows a representation of dynamic pull-in subsequent to a cyclic-fold bifurcation. Upon a threshold mass increase, voltage increase, or dielectric constant increase, the cyclic-fold bifurcation may adjust its location to the left (corresponding to a lower excitation frequency), as a result the position of the operating point relative to the bifurcation point may change from the point marked (1) in FIG. 8 to the point marked (2) in FIG. 8. This process may precipitate pull-in as the electrostatic actuator response increases beyond the amplitude indicated at the point marked (1) without a finite limit until plates 112 pull-in. In embodiments using sub-critical period doubling bifurcation or sub-critical Hopf bifurcation and in some embodiments using cyclic-fold bifurcation, a non-linear controller may be further included in system 50 which may be used to implement a closed-loop feedback control system that may monitor an output signal describing the actuator motions and change the input voltage accordingly to create the bifurcation, or, in some other embodiments, a specially shaped non-harmonic signal may be produced by a voltage regulator to create a regular harmonic response in electrostatic actuator 102 which may tend to provide the desired bifurcation, or, in some other embodiments, specially shaped and placed electrodes and deformable members may be used to provide the desired bifurcation.

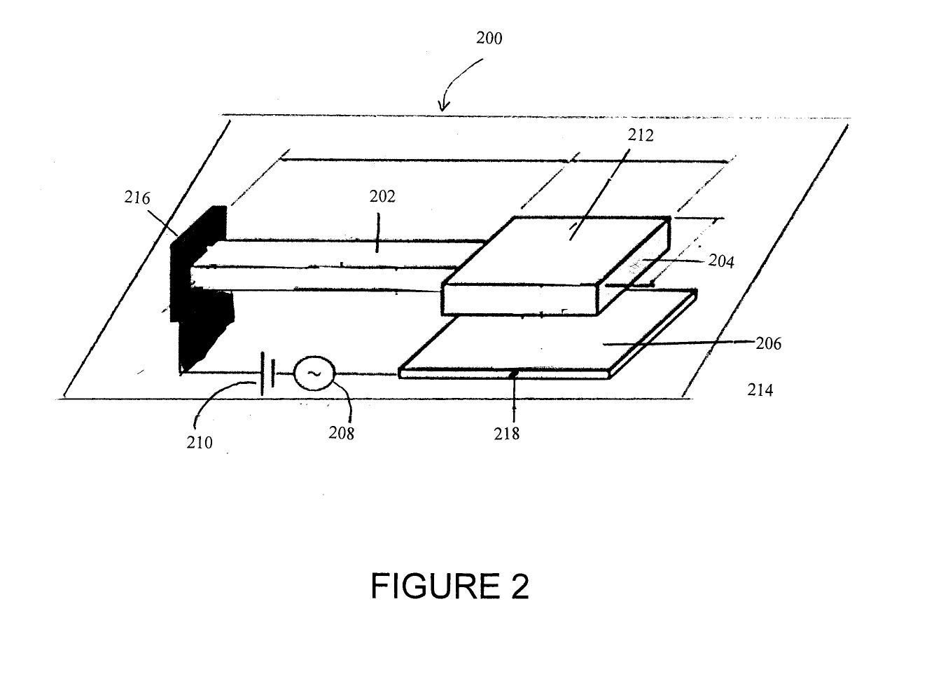

With reference to FIG. 2, a block diagram of the components of the electrostatic mass sensor of FIG. 1 is shown. The electrostatic mass detection sensor 200 comprises a cantilever arm 202, a capacitor having plates 204 and 206, each of plates 204 and 206 electrically connected to AC voltage source 208 and DC voltage source 210. Mass detection platform 212 is connected to plate 204 for receiving a mass when electrostatic mass detection sensor 200 is in operation. Cantilever arm 202 may be connected to post 216 which may be further connected to substrate 218.

Plate 206 may be connected to substrate 218 and may additionally comprise signal line 218. In operation, when pull-in is obtained, plate 204 and plate 206 may come into contact due to movement of cantilever arm 202, which may tend to provide a signal link indicative of detection of a threshold mass detection. In some embodiments, a signal link can be the creation of a signal through signal line 218 and in other embodiments a signal link may be the interruption of a signal in signal line 218. For example, in some embodiments, the resulting capacitive impedance between plate 204 and plate 206 at pull-in may tend to cut communication along signal line 218, which may tend to provide a signal to indicate a binary change of state of threshold-type electrostatic sensor 200, which may tend to indicate that a threshold value of measurement has been met.

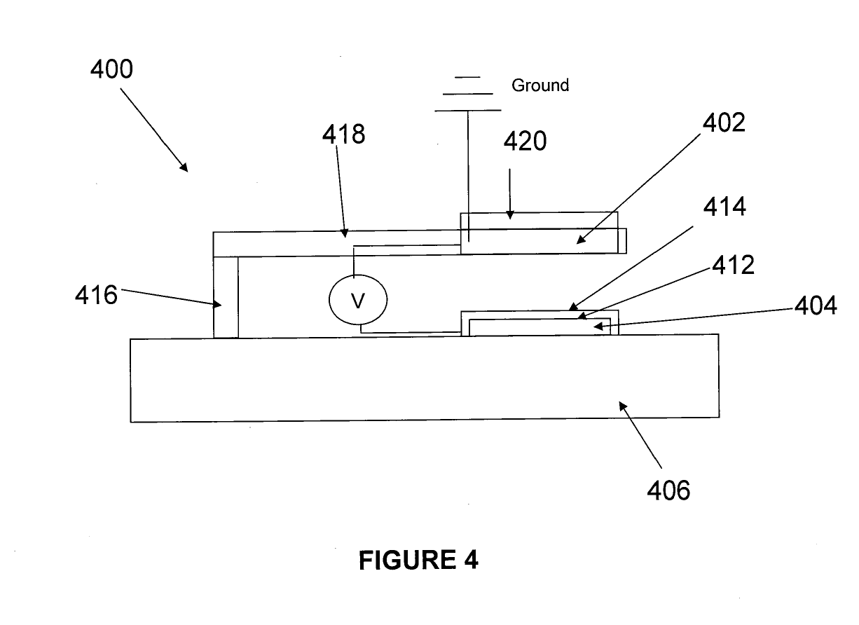

Threshold-type electrostatic sensor 100 can be fabricated using precision machining or micro-electro-mechanical fabrication or nano-electro-mechanical fabrication. With reference to FIG. 4, threshold-type electrostatic sensor 400 is shown, comprising substrate 406, which in some embodiments may be made of polycrystalline silicon. Post 416 is connected to substrate 406, extending away from a surface of substrate 406. Cantilever arm 418 may be connected to post at one end and upper plate 402 may be connected to cantilever arm 418 near the other end. Detection surface 420 may optionally be connected to cantilever arm. Lower plate 404 may be connected to substrate and may be aligned with upper plate 402. Lower plate 404 and upper plate 402 may tend to form a capacitor which may operate as an electrostatic actuator for threshold-type electrostatic sensor 400. Upper plate 402 and lower plate 404 may be electrically connected such that the operation voltage is applied between upper plate 402 and lower plate 404. In an embodiment, upper plate 402 may be connected to ground and lower plate 404 is connected to high (or low) voltage.

Signal line 412 may pass between upper plate 402 and lower plate 404 and in some embodiments, signal line 412 may be insulated with insulation 414 which may tend to allow threshold-type electrostatic sensor 400 to be reused, while in other embodiments signal line 412 may not be insulated which may tend to provide threshold-type electrostatic sensor 400 only one use. In operation, when pull-in is obtained, the resulting capacitive impedance between upper plate 402 and lower plate 404 may tend to cut communication along signal line 412, which may tend to provide a signal to indicate a binary change of state of threshold-type electrostatic sensor 400, which may tend to indicate that a threshold value of measurement has been met.

Cantilever arm 202, in the embodiment shown in FIG. 2, is described with respect to the following geometric properties: width b, thickness h, cross-section area A, and second moment of area I. The relevant material properties of the cantilever arm 202 are the density ρ and Young's modulus E. Mass detection platform 212 may have a mass \hat{m}ₚ located at its center of mass, which may be a distance \hat{L}_{c} from the end of cantilever arm 202. The equation of motion for electrostatic mass detection sensor 200 is represented by:

ωₜₜ(x,t)+cωₜ(x,t)+wₓₓₓₓ(x,t)=0 Equation 1

where cantilever arm 202 deflection ω(x) has been nondimensionalized with respect to the capacitor gap d, the position along the cantilever arm 202 x has been nondimensionalized with respect to the total cantilever arm 202 length L, and time t has been nondimensionalized with respect to the time constant

$$T = \sqrt{\frac{ρ {AL}^{4}}{EI}} .$$

The associated boundary conditions are represented by the following equations:

$$\begin{matrix} ω ( 0 , t ) = 0 , {ω}_{x} ( 0 , t ) = 0 & Equation 2 \\ {ω}_{xx} ( 1 , t ) = {ML}_{c} - {ML}_{c} {ω}_{tt} ( 1 , t ) - \frac{4}{3} {ML}_{c}^{2} {ω}_{xtt} ( 1 , t ) + \frac{{α ( {V}_{DC} + {V}_{AC} ( t ) )}^{2}}{{ω}_{x}^{2} ( 1 , t )} \times [ \begin{matrix}\frac{2 {L}_{c} {ω}_{x} ( 1 , t )}{1 - ω ( 1 , t ) - 2 {L}_{c} {ω}_{x} ( 1 , t )} - \\ ln ( \frac{1 - ω ( 1 , t )}{1 - ω ( 1 , t ) - 2 {L}_{c} {ω}_{x} ( 1 , t )} )\end{matrix} ] & Equation 3 \\ {ω}_{xxx} ( 1 , t ) = M + M {ω}_{tt} ( 1 , t ) + {ML}_{c} {ω}_{xtt} ( 1 , t ) - \frac{{α ( {V}_{DC} + {V}_{AC} ( t ) )}^{2}}{{ω}_{x} ( 1 , t )} [ \begin{matrix}\frac{1}{1 - ω ( 1 , t ) - 2 {L}_{c} {ω}_{x} ( 1 , t )} - \\ \frac{1}{1 - ω ( 1 , t )}\end{matrix} ] & Equation 4\end{matrix}$$

where ∈ is the permittivity of air, and c is the nondimensionalized dampening coefficient. The nondimensionalized parameters appearing in the boundary conditions may be defined by:

$$α = \frac{ɛ {b}_{p} {L}^{4}}{2 {EId}^{3}} , {L}_{c} = \frac{{\hat{L}}_{c}}{L} , M = \frac{{\hat{m}}_{p}}{ρ AL}$$

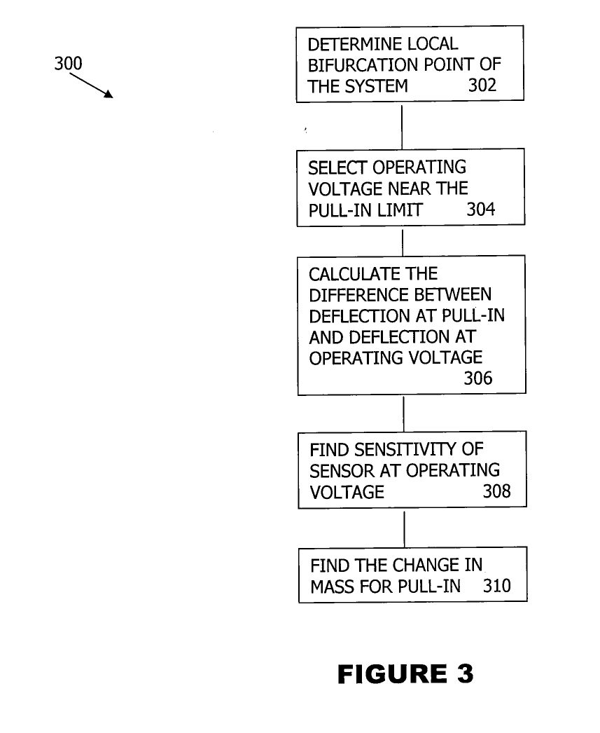

With respect to the above referenced non dimensional equation for motion, and with further reference to FIG. 3, the steps in an exemplary embodiment of a method 300 for determining the threshold mass of electrostatic mass detection sensor 200 is shown. Method 300 begins at step 302, where the local bifurcation threshold value of electrostatic mass detection sensor 200 is determined. This may be done through trial and error methods. For a static bifurcation, the voltage drop across the sense capacitor can be increased in steps and the deflection can be recorded until pull-in occurs. The voltage can then be decreased in steps and the displacement may be recorded until the voltage reaches zero. The deflections can be measured using, for example, a White Light Profilometer. The deflection-DC voltage curve of the actuator can then be constructed from these results which may tend to represent the cantilever arm deflection versus actuator DC voltage. For a dynamic bifurcation, the beam can be excited with a voltage drop made of a DC component and an AC component where the amplitude of the AC component can be held constant while the frequency is swept up and down in the neighborhood of one of the resonances of the electrostatic actuator. The motions of the beam can be measured using, for example, a piezoresistive bridge placed at the root of the cantilever arm 202 or an optical method, such as a vibrometer focused on a point along the span of the cantilever arm 202. The frequency-response curve of the actuator can then be constructed from these results which may tend to represent the response amplitude versus excitation frequency. Individuals skilled in the art will recognize that the deflection-DC voltage curve and frequency-response curve of the electrostatic actuator and functionally equivalent curves can obtained using other experimental and analytical techniques.

Static and dynamic local bifurcations can be identified from the deflection-DC voltage or frequency-response curves by identifying the locations on the curve where the deflection of the cantilever arm 202 approaches the size of the capacitor gap or the amplitude of the cantilever arm 202 response in the frequency up-sweep is different from the response in the down-sweep, respectively. For static bifurcations, each of the local bifurcation points can have a safe side where pull-in may not occur and an unsafe side where pull-in can occur if other solutions are not available or are faraway (possible motions are large). For a static bifurcation, the operating point of the actuator can be placed on the safe side of the local bifurcation and then the DC voltage can be increased to move the operating point to the unsafe side. In such embodiments, it may be found that if the actuator does not land on any other finite solution, the actuator may provide pull-in and the local bifurcation point may be operable to provide sensing. For a dynamic bifurcation, the operating point of the actuator may be placed on the safe side of the local bifurcation and then the amplitude or the frequency of the AC voltage can be increased or decreased (depending on the location of the bifurcation) to move the operating point to the unsafe side. In such embodiments, it may be found that if the actuator does not land on any other finite solution, the actuator may provide dynamic pull-in and the local bifurcation point may be operable to provide sensing.

Once the local bifurcation threshold value is determined at step 302, an operating voltage may be selected at step 304. In an embodiment, the operating voltage can be set at a point close to the pull-in threshold where experimental trial and error or analytical formulae have shown that the a pre-set mass, voltage increase or dielectric constant increase is enough to shift the operating point from the safe to the unsafe side of the local bifurcation.

To determine the minimum detectable mass, or the threshold mass, to be detected by electrostatic mass detection sensor 200, at step 306, the difference between the deflection of cantilever arm 202 at the pull-in threshold and at the operating voltage is determined.

In static embodiments of electrostatic mass detection sensor 200, such as those having DC voltage source 210 but no AC voltage source 208, the static deflection ωₛ of cantilever arm 202 may be subject to the electrostatic force and the weight of mass detection platform 212. In some embodiments, the weight of cantilever arm 202 may be found to be negligible and may not need to be taken into account in calculating such deflection. The static problem is formulated by setting the time derivative and the AC forcing terms equal to zero, which provides the following equations:

$$\begin{matrix} {ω}_{s}^{iv} ( x ) = 0 & Equation 5 \\ {ω}_{s} ( 0 ) = 0 , {ω}_{s}^{′} ( 0 ) = 0 & Equation 6 \\ {ω}_{s}^{″} ( 1 ) = {ML}_{c} + \frac{α {V}_{DC}^{2}}{{( {ω}_{s}^{′} ( 1 ) )}^{2}} \times [ \begin{matrix}\frac{2 {L}_{c} {ω}_{s}^{′} ( 1 )}{1 - {ω}_{s} ( 1 ) - 2 {L}_{c} {ω}_{s}^{′} ( 1 )} - \\ ln ( \frac{1 - {ω}_{s} ( 1 )}{1 - {ω}_{s} ( 1 ) - 2 {L}_{c} {ω}_{s}^{′} ( 1 )} )\end{matrix} ] & Equation 7 \\ {ω}_{s}^{′′′} ( 1 ) = M - \frac{α {V}_{DC}^{2}}{{ω}_{s}^{′} ( 1 )} [ \frac{1}{1 - {ω}_{s} ( 1 ) - 2 {L}_{c} {ω}_{s}^{′} ( 1 )} - \frac{1}{1 - {ω}_{s} ( 1 )} ] & Equation 8\end{matrix}$$

Using the general solution of:

ωₛ(x)=Ax³+Bx²+Cx+D Equation 9

and using the two boundary conditions of C=D=0, and substituting, the following two nonlinear algebraic equations are arrived at:

$$\begin{matrix}6 A + 2 B = {ML}_{c} + \frac{α {V}_{DC}^{2}}{{( 3 A + 2 B )}^{2}} [ \begin{matrix}\frac{2 {L}_{c} ( 3 A + 2 B )}{\begin{matrix}1 - A - B - \\ 2 {L}_{c} ( 3 A + 2 B )\end{matrix}} - \\ ln ( \frac{1 - A - B}{\begin{matrix}1 - A - B - \\ 2 {L}_{c} ( 3 A + 2 B )\end{matrix}} )\end{matrix} ] & Equation 10 \\ 6 A = - M + \frac{α {V}_{DC}^{2}}{3 A + 2 B} [ \begin{matrix}\frac{1}{1 - A - B} - \\ \frac{1}{1 - A - B - 2 {L}_{c} ( 3 A + 2 B )}\end{matrix} ] & Equation 11\end{matrix}$$

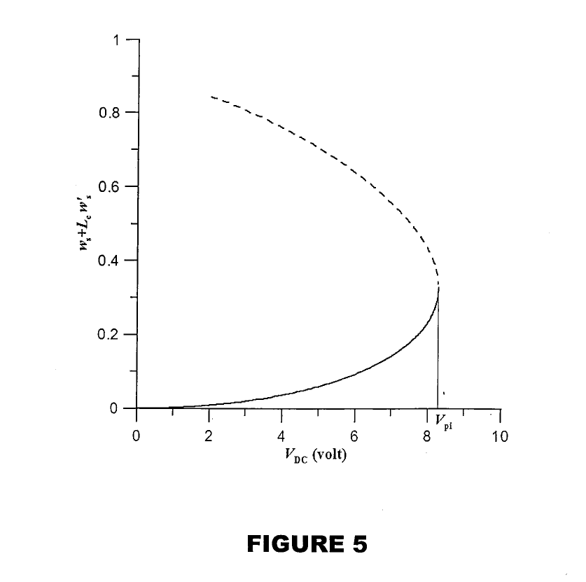

Using Equations 10 and 11, as an example, in an embodiment of electrostatic mass detection sensor 200 wherein cantilever arm 202 has a length of 250 μm, a width of 5 μm and a thickness of 1.5 μm, and where mass detection plate has a length of 50 μm, a width of 20 μm and a thickness of 1.5 μm, and the distance between plates 204 and 206 is 4 μm and the air permittivity (∈) is 8.854×10⁻¹² F/m and the structural material of electrostatic mass sensor 100 is polysilicon with ρ=2300 Kg/m³ and E=160 GPa, it has been found that the pull-in threshold of the electrostatic mass detection sensor 200 may be 8.3 volts and the variation of the static deflection of the mass detection plate 212 center of mass is 0.3282 of the initial gap between plates 204 and 206. With additional reference to FIG. 5, the variation of the static deflection ωₛ+L_{c}ω′ₛ of mass detection plate 212 versus the voltage provided by DC voltage source 210 is shown.

Method 300 then proceeds to step 308, where the sensitivity of electrostatic mass detection sensor 200 at the operating voltage may be determined. This is represented by the ratio of the change in the static deflection of mass detection plate 212 δωₛ to the change δm in the mass, which is represented by the following equation:

$${S}_{m} = \frac{δ {ω}_{s}}{δ m} \qquad Equation 12$$

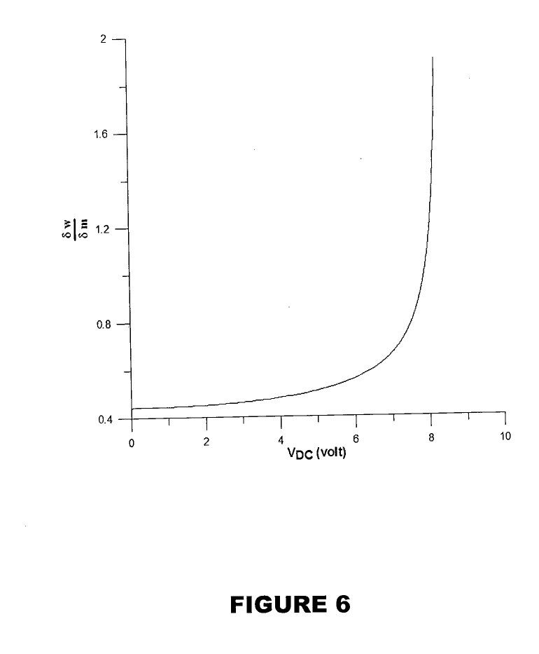

The static deflection of mass detection plate 212 is found by the following equation:

$${ω}_{s} ( 1 + {L}_{c} ) = {Ax}^{3} + {Bx}^{2} + {L}_{c} {ω}_{s}^{′} ( 1 ) \\ ⇒ δ {ω}_{s} = ( 1 + 3 {L}_{c} ) δ A + ( 1 + 2 {L}_{c} ) δ B \qquad Equation 13$$

where δA and δB are perturbations in A and B due to changes δm in the mass, the sensitivity of the electrostatic mass detection sensor 200 is shown as a function of the operating voltage V_{CD}, as can be seen in FIG. 6. The sensitivity is found to be increased near the pull-in limit, thus, a small mass added to mass detection plate 212 may be more detectable near the pull-in limit than away from it, meaning that it is advantageous to operate electrostatic mass detection sensor 200 close to the pull-in limit.

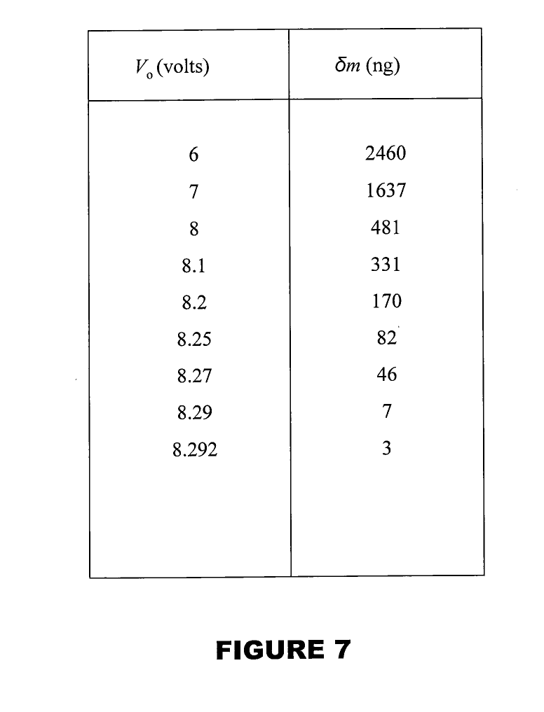

At step 310, the change in mass needed for electrostatic mass detection sensor 200 is found using Equation 12 described above, solving for δm with the previously calculated change in deflection δwₛ and sensitivity at the operating voltage Sₘ. The addition of this calculated change in mass represents the threshold mass amount that can be added to the system 50 changing the local bifurcation point such that the threshold voltage resulting in pull-in is less than the operating voltage, thus, sending electrostatic mass detection sensor 200 into pull-in. When the electrostatic mass detection sensor has been sent to pull-in this indicates the presence of a mass. FIG. 7 shows some minimum detectable masses versus the operating voltage for an embodiment of electrostatic mass detection sensor 200.

In dynamic embodiments of electrostatic mass detection sensor 200, such as those having DC voltage source 210 and AC voltage source 208, electrostatic mass detection sensor may be modeled by expressing the Lagrangian of the system, which may be represented by the following equation:

$$£ = {\int }_{0}^{1} {ω}_{t}^{2} d x + {M [ {ω}_{t} ( 1 , t ) + {L}_{c} {ω}_{xt} ( 1 , t ) ]}^{2} + \frac{1}{3} {ML}_{C}^{2} {ω}_{xt}^{2} ( 1 , t ) - {\int }_{0}^{1} {ω}_{xx}^{2} d x + 2 {M}_{b} {\int }_{0}^{1} ω ( x , t ) d x + 2 {MM}_{b} ( {L}_{c} {ω}_{x} ( 1 , t ) + ω ( 1 , t ) ) - 2 α \frac{{( {V}_{DC} + {V}_{AC} ( t ) )}^{2}}{{ω}_{x} ( 1 , t )} ln ( \frac{1 - ω ( 1 , t ) - 2 {L}_{c} {ω}_{x} ( 1 , t )}{1 - ω ( 1 , t )} ) \\ where \\ {M}_{b} = \frac{{ρ}_{g} {AL}^{3}}{EId} . \qquad Equation 14$$

The response of electrostatic mass detection sensor 200 is composed of a static and a dynamic component and is expressed as:

$$ω ( x , t ) = {ω}_{s} ( x ) + {\sum }_{i = 1}^{n} {q}_{i} ( t ) {φ}_{i} ( x ) \qquad Equation 15$$

where φᵢ(x) are the mode shapes of the beam-plate system and the qᵢ(t) are the generalized coordinates. By substituting Equation 15 into Equation 14 and writing the Euler-Lagrange equations, the following n-dimensional reduced-order model is obtained:

$${\sum }_{j = 1}^{n} ( {M}_{ij} {\ddot{q}}_{j} + {D}_{ij} {\dot{q}}_{j} + {K}_{ij } {q}_{j} = - {\int }_{0}^{1} {ω}_{s}^{″} ( x ) {φ}_{i}^{″} ( x ) d x + \frac{α}{Γ} {( {V}_{DC} + {V}_{AC} )}^{2} ln [ κ - {\sum }_{j = 1}^{n} ( \begin{matrix}{φ}_{j} ( 1 ) - \\ 2 {L}_{c} {φ}_{j}^{′} ( 1 )\end{matrix} ) {q}_{j} ] - \frac{α}{Γ} {( {V}_{DC} + {V}_{AC} )}^{2} ln ( χ - {\sum }_{j = 1}^{n} {φ}_{j} ( 1 ) {q}_{j} ) + \frac{2 α {L}_{c}}{Λ} {( {V}_{DC} + {V}_{AC} )}^{2} [ \begin{matrix}{χφ}_{i}^{′} ( 1 ) + {ω}_{s}^{′} ( 1 ) {φ}_{i} ( 1 ) + \\ {\sum }_{j = 1}^{n} ( \begin{matrix}{φ}_{j}^{′} ( 1 ) {φ}_{i} ( 1 ) - \\ {φ}_{j} ( 1 ) {φ}_{i}^{′} ( 1 )\end{matrix} ) {q}_{j}\end{matrix} ] , \\ i = 1 , 2 , … , n \\ where \\ χ = 1 - {ω}_{s} ( x ) , \\ κ = 1 - {ω}_{s} ( x ) - 2 {L}_{c} {ω}_{s}^{′} ( x ) , \\ and \\ {M}_{ij} = {\int }_{0}^{1} {φ}_{i} ( x ) {φ}_{j} ( x ) d x + \frac{1}{3} {ML}_{c}^{2} {φ}_{i}^{′} ( 1 ) {φ}_{j}^{′} ( 1 ) + \frac{1}{4} M [ \begin{matrix}2 {φ}_{i} ( 1 ) + \\ 2 {L}_{c} {φ}_{i}^{′} ( 1 )\end{matrix} ] [ \begin{matrix}2 {φ}_{j} ( 1 ) + \\ 2 {L}_{c} {φ}_{j}^{′} ( 1 )\end{matrix} ] \\ {K}_{ij} = {\int }_{0}^{1} {φ}_{j}^{″} ( x ) {φ}_{j}^{″} ( x ) d x + {M}_{b} {\int }_{0}^{1} {φ}_{i} ( x ) d x + {MM}_{b} [ \begin{matrix}{\sum }_{i = 1}^{n} {φ}_{i} ( 1 ) + \\ {L}_{c} {\sum }_{i = 1}^{n} {φ}_{i}^{′} ( 1 )\end{matrix} ] \\ {D}_{ij} = c {\int }_{0}^{1} {φ}_{i} ( x ) {φ}_{j} ( x ) d x \\ Γ = {[ {\sum }_{j = 1}^{n} {φ}_{j}^{′} ( 1 ) {q}_{j} + {ω}_{s}^{′} ( 1 ) ]}^{2} \\ Λ = {[ χ - {\sum }_{j = 1}^{n} {φ}_{j} ( 1 ) {q}_{j} ]}^{2} [ {\sum }_{j = 1}^{n} {φ}_{j}^{′} ( 1 ) {q}_{j} + {ω}_{s}^{′} ( 1 ) ] \times \{ κ - {\sum }_{j = 1}^{n} [ \begin{matrix}{φ}_{j} ( 1 ) - \\ 2 {L}_{c} {φ}_{j}^{′} ( 1 )\end{matrix} ] {q}_{j} \} \qquad Equation 16$$

A one-mode approximation may be sufficient to capture the full dynamics of the system, which would have the effect of reducing the order of the model described in Equation 16 to the following equation:

$${M}_{11} {\ddot{q}}_{j} + {D}_{11} {\dot{q}}_{j} + {K}_{11} {q}_{j} = - {\int }_{0}^{1} {ω}_{s}^{″} ( x ) {φ}_{1}^{″} ( x ) d x + \frac{{α ( {V}_{DC} + {V}_{AC} )}^{2}}{{( {φ}_{1}^{′} ( 1 ) {q}_{1} + {ω}_{s}^{′} ( 1 ) )}^{2}} ln \frac{κ - ( {φ}_{1} ( 1 ) + 2 {L}_{c} {φ}_{1}^{′} ( 1 ) ) {q}_{1}}{χ - {φ}_{1} ( 1 ) {q}_{1}} + \frac{2 α {{L}_{c} ( {V}_{DC} + {V}_{AC} )}^{2} [ {χφ}_{1}^{′} ( 1 ) + {ω}_{s}^{′} ( 1 ) {φ}_{1} ( 1 ) ]}{( χ - {φ}_{1} ( 1 ) {q}_{1} ) ( {φ}_{1}^{′} ( 1 ) {q}_{1} + {ω}_{s}^{′} ( 1 ) ) [ κ - ( \begin{matrix}{φ}_{1} ( 1 ) + \\ 2 {L}_{c} {φ}_{1}^{′} ( 1 )\end{matrix} ) {q}_{1} ]} \qquad Equation 17$$

When operating electrostatic mass detection sensor 200 at an operating voltage of V_{DC}=7 volts and V_{AC}=0.1 cos(Ωt) volts it may be found that cyclic-fold local bifurcation occurs at Ω=1.08. Thus, operating electrostatic mass detection sensor 200 just to the left of the cyclic-fold local bifurcation point, as mass is absorbed by or adsorbed to mass detection plate 212, the cyclic-fold local bifurcation frequency may be gradually shifted to the left until enough mass is added to move the local bifurcation frequency to the left of the operating point of electrostatic mass detection sensor 200, thereby inducing pull-in. In other embodiments, a subcritical period-doubling local bifurcation, a subcritical period-doubling local bifurcation or a subcritical Hopf local bifurcation may cause local bifurcation.

It has been found that the sensitivity of cantilever arm 202 may be inversely proportional to the thickness of cantilever arm 202. Thus, it may tend to improve the sensitivity of electrostatic mass detection sensor 200 by decreasing the structural thickness of cantilever arm 202 and mass detection plate 212.

The present invention has been described with regard to specific embodiments. However, it will be obvious to persons skilled in the art that a number of variants and modifications can be made without departing from the scope of the invention as described herein.

What is claimed is:

1. A threshold-type electrostatic sensor for detecting a threshold value of mass comprising:
a deformable member with a mass detection area thereon;
an electrostatic actuator having a first plate and a second plate, the first plate being connected to the mass detection area; and
a voltage source connected to each of the first and second plates, the voltage source providing an operating voltage to the actuator, the operating voltage being proximate to a local bifurcation point of the electrostatic sensor for the first and second plates to pull-in together,
wherein upon an external mass having the threshold value appearing on the mass detection area, the local bifurcation point of the electrostatic sensor is shifted such that the first and second plates will pull-in to contact each other by movement of the deformable member, the contact providing signalling indicative of detection of the threshold value of the external mass.

2. The threshold-type electrostatic sensor of claim 1, further comprising an output device for receiving the signaling of detection of the external mass.

3. The threshold-type electrostatic sensor of claim 2, wherein the second plate is mounted on a substrate and the first plate is mounted over the second plate by way of the deformable member attached to a post on the substrate.

4. The threshold-type electrostatic sensor of claim 3, wherein the pull-in of the first and second plates is by static pull-in.

5. The threshold-type electrostatic sensor of claim 4, wherein the local bifurcation point is determined by saddle-node bifurcation.

6. The threshold-type electrostatic sensor of claim 4 further comprising a non-linear controller electrically connected to the voltage source and the electrostatic actuator, wherein the local bifurcation point is determined by any one of sub-critical pitch-fork bifurcation or saddle-node bifurcation.

7. The threshold-type electrostatic sensor of claim 3, wherein the pull-in of the first and second plates is by dynamic pull-in.

8. The threshold-type electrostatic sensor of claim 7 wherein the local bifurcation point is determined by cyclic-fold bifurcation.

9. The threshold-type electrostatic sensor of claim 7 further comprising a non-linear controller electrically connected to the voltage source and the electrostatic actuator and the local bifurcation point is determined by any one of sub-critical period doubling bifurcation, sub-critical Hopf bifurcation or cyclic-fold bifurcation.

10. A threshold-type electrostatic sensor for detecting a threshold value of a concentration of an analyte comprising:
a deformable member;
an electrostatic actuator having a first plate and a second plate and a concentration detection region therebetween; and
a voltage source connected to each of the first and second plates, the voltage source providing an operating voltage to the actuator, the operating voltage being proximate to a local bifurcation point of the electrostatic sensor for the first and second plates to pull-in together,
wherein upon an external concentration of an analyte having the threshold value appearing in the detection region, the local bifurcation point of the electrostatic sensor is shifted such that the first and second plates will pull-in to contact each other by movement of the deformable member, the contact providing signalling indicative of detection of the threshold value of the external concentration of the analyte.

11. The threshold-type electrostatic sensor of claim 10, further comprising an output device for receiving the signaling of detection of the concentration of the analyte.

12. The threshold-type electrostatic sensor of claim 11, wherein the second plate is mounted on a substrate and the first plate is mounted over the second plate by way of the deformable member attached to a post on the substrate.

13. The threshold-type electrostatic sensor of claim 12, wherein the pull-in of the first and second plates is by static pull-in.

14. The threshold-type electrostatic sensor of claim 13, wherein the local bifurcation point is determined by saddle-node bifurcation.

15. The threshold-type electrostatic sensor of claim 13 further comprising a non-linear controller electrically connected to the voltage source and the electrostatic actuator, wherein the local bifurcation point is determined by any one of sub-critical pitch-fork bifurcation or saddle-node bifurcation.

16. The threshold-type electrostatic sensor of claim 12, wherein the pull-in of the first and second plates is by dynamic pull-in.

17. The threshold-type electrostatic sensor of claim 16 wherein the local bifurcation point is determined by cyclic-fold bifurcation.

18. The threshold-type electrostatic sensor of claim 16 further comprising a non-linear controller electrically connected to the voltage source and the electrostatic actuator and the local bifurcation point is determined by any one of sub-critical period doubling bifurcation, sub-critical Hopf bifurcation or cyclic-fold bifurcation.

19. The threshold-type electrostatic sensor of claim 12 further comprising a circuit element made of a detector material connected to the first and second plates for adjustment of impedance therebetween in the presence of the analyte.
